(19) United States
(12) Patent Application Publication
(10) Pub. No.: US 2018/0083596 A1
(43) Pub. Date: Mar. 22, 2018

(54) TUNING-FORK TYPE CRYSTAL RESONATOR

(71) Applicant: NIHON DEMPA KOGYO CO., LTD., Tokyo (JP)

(72) Inventors: Yoshiteru SATO, Saitama (JP); Shingo KAWANISHI, Saitama (JP)

(73) Assignee: NIHON DEMPA KOGYO CO., LTD., Tokyo (JP)

(21) Appl. No.: 15/702,723

(22) Filed: Sep. 12, 2017

(30) Foreign Application Priority Data
Sep. 16, 2016 (JP) 2016-181097

(51) Int. Cl. H03H 9/13; H03H 9/21

(52) U.S. Cl. CPC H03H 9/13; H03H 9/21

(57) ABSTRACT

A tuning-fork type crystal resonator includes a base portion, a first vibration arm and a second vibration arm, a supporting arm, a first connection pad and a second connection pad, and a first excitation electrode and a second excitation electrode. The first excitation electrode is extended from the first connection pad so as to reach a side surface of the first vibration arm on the supporting arm side via a region including a part of a principal surface of the supporting arm and a part of a side surface of the supporting arm on the first vibration arm side, an inner bottom surface of a first bifurcated portion present between the supporting arm and the first vibration arm, and a circumferential portion of the first bifurcated portion in the base portion. The second excitation electrode is extended at a second bifurcated portion similarly to the first excitation electrode.

### CROSS-REFERENCE TO RELATED APPLICATIONS

This application is based on and claims priority under 35 U.S.C. § 119 to Japanese Patent Application No. 2016-181097, filed on Sep. 16, 2016, the entire content of which is incorporated herein by reference.

### TECHNICAL FIELD

This disclosure relates to a tuning-fork type crystal resonator that has a feature in a lead-out structure of an electrode.

### DESCRIPTION OF THE RELATED ART

In association with reduction in size of electronic equipment, more and more request for reduction in size to a tuning-fork type crystal resonator has increased. One of advantageous structures for the reduction in size of a tuning-fork type crystal resonator includes, what is called, a tuning-fork type crystal resonator with a three-arm structure. The tuning-fork type crystal resonator includes: a base portion; two vibration arms extending in parallel with one another from the base portion; and a supporting arm extending between these supporting arms from the base portion.

In the case of a tuning-fork type crystal resonator, as it is well known, it is necessary to extend a first excitation electrode and a second excitation electrode that are electrically separated as predetermined to total eight surfaces including principal surfaces and side surfaces of respective vibration arms. A tuning-fork type crystal resonator with a three-arm structure employs a structure that arranges a part of each of a first excitation electrode and a second excitation electrode on a supporting arm and uses the portions as connection pads with a package. Examples of such structure are disclosed by, for example, FIG. 5 of Japanese Unexamined Patent Application Publication No. 2003-163568, FIG. 1 of Japanese Unexamined Patent Application Publication No. 2010-259023, and similar Japanese Unexamined Patent Application Publication.

### SUMMARY

According to a first aspect of this disclosure, there is provided a tuning-fork type crystal resonator. The tuning-fork type crystal resonator includes a base portion, a first vibration arm and a second vibration arm, a supporting arm, a first connection pad and a second connection pad, and a first excitation electrode and a second excitation electrode. The first vibration arm and a second vibration arm are parallelly extending from the base portion. The supporting arm extends from the base portion between the first vibration arm and the second vibration arm. The first connection pad and a second connection pad are disposed on a part of the supporting arm to connect to outside. The first excitation electrode and the second excitation electrode respectively extended from the first connection pad and the second connection pad to the first vibration arm and the second vibration arm. The first excitation electrode is extended from the first connection pad so as to reach a side surface of the first vibration arm on a supporting arm side, via a region including a part of a principal surface of the supporting arm and a part of a side surface of the supporting arm on a first vibration arm side, an inner bottom surface of a first bifurcated portion present between the supporting arm and the first vibration arm, and a circumferential portion of the first bifurcated portion in the base portion. The second excitation electrode is extended from the second connection pad so as to reach a side surface of the second vibration arm on a supporting arm side, via a region including a part of the principal surface of the supporting arm and a part of a side surface of the supporting arm on a second vibration arm side, an inner bottom surface of a second bifurcated portion present between the supporting arm and the second vibration arm, and a circumferential portion of the second bifurcated portion in the base portion.

### BRIEF DESCRIPTION OF THE DRAWINGS

The foregoing and additional features and characteristics of this disclosure will become more apparent from the following detailed description considered with reference to the accompanying drawings, wherein:

FIG. 1A and FIG. 1B are drawings describing a general structure of a tuning-fork type crystal resonator with a three-arm structure.

FIG. 2 is a drawing describing a structural example of excitation electrodes of a tuning-fork type crystal resonator with a three-arm structure.

FIG. 3A is a drawing describing a main portion of a tuning-fork type crystal resonator of a working example.

FIG. 3B is a drawing describing a main portion of a tuning-fork type crystal resonator of a comparative example.

FIG. 4A is a drawing describing an electrostatic withstand voltage property of the tuning-fork type crystal resonator of the working example.

FIG. 4B is a drawing describing an electrostatic withstand voltage property of the tuning-fork type crystal resonator of the comparative example.

FIG. 5 is a SEM photograph describing a position having been broken down by static electricity in the tuning-fork type crystal resonator of the comparative example.

### DETAILED DESCRIPTION

The following describes embodiments of a tuning-fork type crystal resonator according to this disclosure with reference to drawings. Each drawing used in the description is merely illustrated schematically for understanding this disclosure. In each drawing used in the description, like reference numerals designate corresponding or identical elements, and therefore such elements may not be further elaborated here. Shapes, dimensions, materials, and similar factor described in the following embodiments are merely preferable examples within the scope of this disclosure. Therefore, the disclosure is not limited to only the following embodiments.

[1. Structure of Tuning-Fork Type Crystal Resonator with Three-Arm Structure]

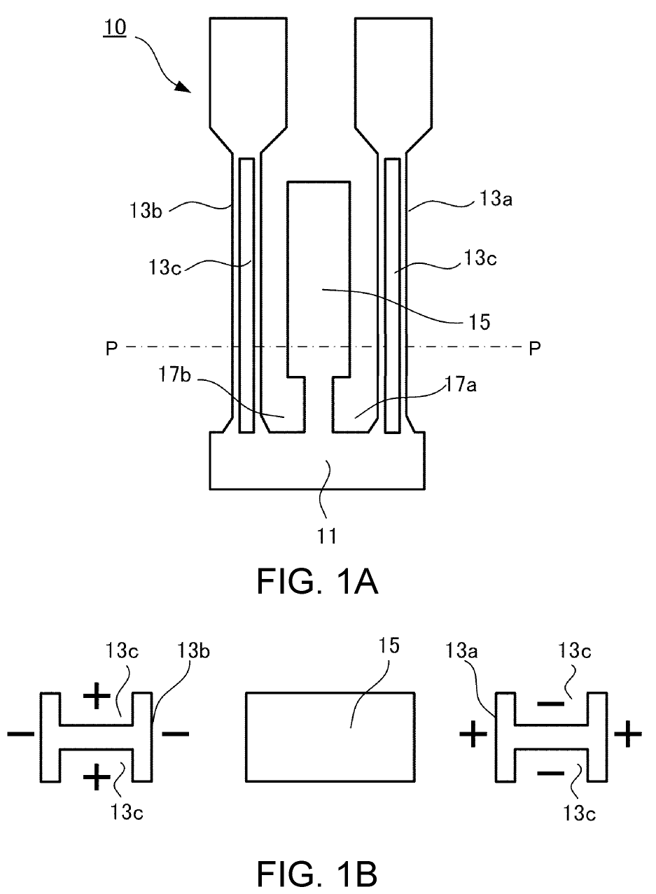

First, a description will be given of a fundamental structure of the tuning-fork type crystal resonator with the three-arm structure for better understanding of this disclosure. FIG. 1A is a plan view of the tuning-fork type crystal resonator, and FIG. 1B is a drawing of a cross section taken along the line P-P in FIG. 1A viewed from the head side of the tuning-fork. FIG. 1A and FIG. 1B are drawings focused on a crystal element of a tuning-fork type crystal resonator 10 and omit illustrations such as a container that houses and fixes the crystal element and an excitation electrode formed on the crystal element.

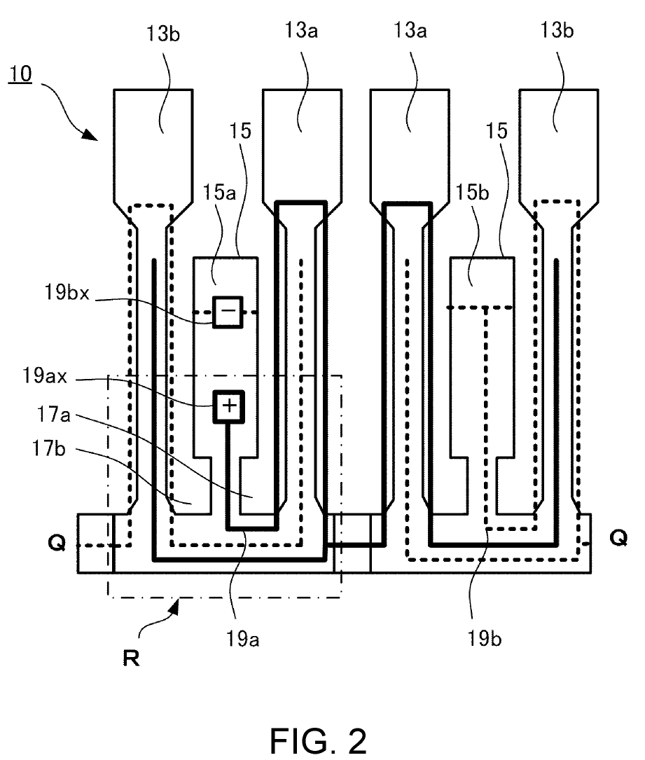

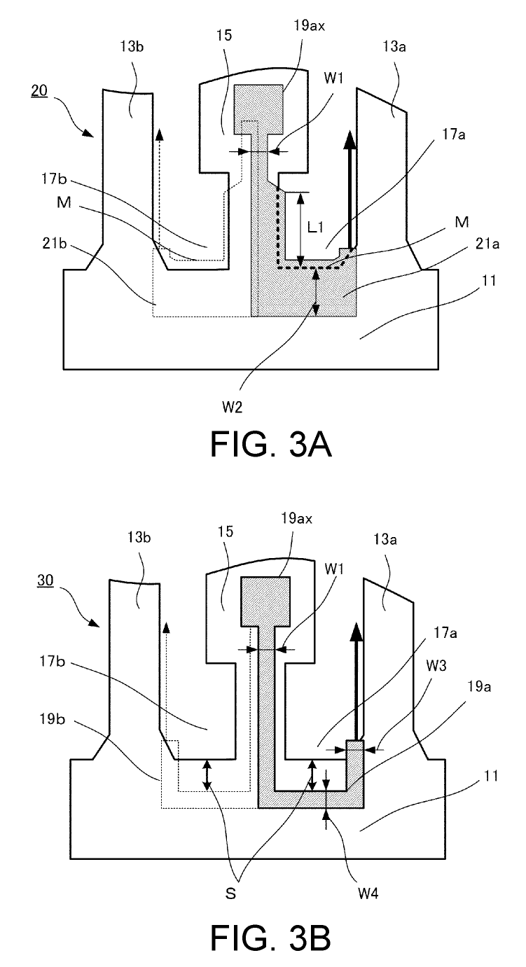

The tuning-fork type crystal resonator 10 includes a base portion 11, a first vibration arm 13a and a second vibration arm 13b, a supporting arm 15, grooves 13c, and the excitation electrodes (see FIG. 2). The first vibration arm 13a and the second vibration arm 13b extend in parallel with one another from the base portion 11. Each of the first vibration arm 13a and the second vibration arm 13b in this case has a distal end portion with a width wider than those of their other portions. The grooves 13c are provided with a predetermined depth on both the front and back surfaces of each of the first vibration arm 13a and the second vibration arm 13b. The grooves 13c are provided for efficiently applying an electric field of a drive signal to the tuning-fork type crystal resonator 10. In the following FIG. 2, FIG. 3A, and FIG. 3B, illustration of the grooves are omitted. Between the first vibration arm 13a and the second vibration arm 13b, the supporting arm 15 extends from the base portion 11 in a state parallel to these vibration arms. Consequently, a first bifurcated portion 17a is formed between the supporting arm 15 and the first vibration arm 13a, and a second bifurcated portion 17b is formed between the supporting arm 15 and the second vibration arm 13b.

In such tuning-fork type crystal resonator 10, as illustrated in FIG. 1B, a predetermined alternating electric field is applied to total eight surfaces of the principal surfaces and side surfaces of the respective first vibration arm 13a and second vibration arm 13b, so as to generate a flexure vibration. That is, applying an electric field to the vibration arm with polarity indicated by + and − as an example in FIG. 1B at a certain time, and then applying an electric field to the vibration arm with the polarity opposite to the case in FIG. 1B at next time, so as to generate a flexure vibration.

In order to generate such flexure vibration, the excitation electrodes are arranged with respect to the first vibration arm 13a and the second vibration arm 13b. The following describes this with reference to FIG. 2. FIG. 2 corresponds to a developed view of the tuning-fork type crystal resonator 10. That is, the developed view means that folding the developed view in FIG. 2 in a lateral direction of the paper surface and joining the two positions indicated as Q makes a shape of the tuning fork. In FIG. 2, the solid line with numeral 19a indicates a first excitation electrode, and the dashed line with numeral 19b indicates a second excitation electrode. Although actually having a predetermined width, each of these excitation electrodes 19a and 19b is indicated by the solid line or the dashed line in FIG. 2. While these excitation electrodes are also arranged on the side surfaces of the vibration arms 13a and 13b, the portions arranged on the side surfaces of the vibration arms are, for convenience of illustration, indicated in an appearance in which the solid line and the dashed line are drawn along the sides of the vibration arms 13a and 13b.

As can be seen from FIG. 2, the first excitation electrode 19a is extended from a first connection pad 19ax on a first principal surface 15a of the supporting arm 15 to a first side surface of the first vibration arm 13a and a second side surface opposed to the first side surface of the first vibration arm 13a, and a first principal surface of the second vibration arm 13b and a second principal surface opposed to the first principal surface of the second vibration arm 13b. The second excitation electrode 19b is extended from a second connection pad 19bx on the first principal surface 15a of the supporting arm 15 to a second principal surface 15b of the supporting arm 15 via the side surface of the supporting arm 15, and then is extended to a first side surface of the second vibration arm 13b and a second side surface opposed to the first side surface of the second vibration arm 13b, and a first principal surface of the first vibration arm 13a and a second principal surface opposed to the first principal surface of the first vibration arm 13a.

The structure of such tuning-fork type crystal resonator with the three-arm structure is preferably applied to a tuning-fork type crystal resonator of, in a package size of a crystal resonator, for example, equal to or less than 1.6 mm×1.0 mm size, what is called, equal to or less than 1610 size. Specimens of the following working example and comparative example are also examined with 1610 size. Obviously, this size is one example.

[2. Lead-Out Structure and Electrostatic Withstand Voltage Property of Excitation Electrode]

Next, the following describes that a lead-out structure of the excitation electrode influences an electrostatic withstand voltage property of the tuning-fork type crystal resonator, with reference to FIG. 3A to FIG. 5.

[2-1. Structure of Tuning-Fork Type Crystal Resonator of Working Example and Comparative Example]

FIG. 3A is a plan view describing a tuning-fork type crystal resonator 20 of a working example, and FIG. 3B is a plan view describing a tuning-fork type crystal resonator 30 of a comparative example. Both the drawings are the drawings focused on a characterizing portion of the excitation electrode, and are the plan views illustrating a portion corresponding to the portion where R is attached in FIG. 2.

As illustrated in FIG. 3A, in the tuning-fork type crystal resonator 20 of the working example, a first excitation electrode 21a is extended from the first connection pad 19ax so as to reach the side surface of the first vibration arm 13a on the supporting arm 15 side via a region formed of a part of the principal surface of the supporting arm 15 and a part of the side surface of the supporting arm 15 on the first vibration arm 13a side, an inner bottom surface of the first bifurcated portion 17a present between the supporting arm 15 and the first vibration arm 13a, and a circumferential portion of the first bifurcated portion 17a in the base portion 11. That is, in the case of the working example, the excitation electrode 21a is provided beyond a contour M (indicated by the dashed line in FIG. 3A) of the first bifurcated portion 17a and over a part of the side surface of the supporting arm 15 and the inner bottom surface of the first bifurcated portion 17a.

In the tuning-fork type crystal resonator 20 of the working example, a width W1 of the portion provided on the principal surface of the supporting arm 15 in the first excitation electrode 21a was set to be 30 μm. A width W2 of the circumferential portion of the first bifurcated portion 17a of the base portion 11 in the excitation electrode 21a was set to be 50 μm. The portions of the excitation electrode 21a provided on the side surface of the supporting arm 15 and the inner bottom surface of the first bifurcated portion 17a were formed such that approximately all the portions became the excitation electrode in a thickness direction (a direction perpendicular to the paper surface in FIG. 3A) of the tuning-fork type crystal resonator 20.

Although the above-described electrode width and similar width were set to be the above-described values in the experiment, the width W1 is preferably at least 30 μm according to the examination of the inventor. Considering the effect of the disclosure that provides the electrode also on the side surface of the supporting arm and the inner bottom surface of the bifurcated portion, the width W2 of 50 μm is unnecessary, and the width W2 is preferably equal to or more than 20 μm considering convenience of manufacturing. Of the excitation electrode 21a, the portions provided on the side surface of the supporting arm and the bottom surface of the first bifurcated portion 17a does not need to be approximately all in the thickness direction of the tuning-fork type crystal resonator 20 (the direction perpendicular to the paper surface in FIG. 3A), and they are preferably at least a half in the thickness direction. When the excitation electrode is extended onto the side surface of the supporting arm 15, it is preferred that up to which portion of the side surface of the supporting arm to use is determined by a dimension that ensures connection to the excitation electrode provided on the inner bottom surface of the first bifurcated portion. It is preferred that a distance L1 (see FIG. 3A) from the bottom of the bifurcated portion is at least 50 μm, preferably at least about 100 μm; however, it is not limited to this.

On the opposite-side surface of the tuning-fork, a second excitation electrode 21b also is provided beyond the contour of the second bifurcated portion 17b and over a part of the side surface of the supporting arm 15 and an inner bottom surface of the second bifurcated portion 17b. It is preferred that a width of the electrode and a detail of a formation region of the electrode on the side surface of the supporting arm and on the inner bottom surface of the second bifurcated portion 17b are similar to the first excitation electrode.

On the other hand, in the tuning-fork type crystal resonator 30 of the comparative example, as illustrated in FIG. 3B, the first excitation electrode 19a is extended from the first connection pad 19ax so as to reach the side surface of the first vibration arm 13a on the supporting arm 15 side via a part of the principal surface of the supporting arm 15 and a part of the base portion 11. That is, in the case of the comparative example, the first excitation electrode 19a is extended so as to reach the side surface of the first vibration arm 13a on the supporting arm 15 side via a part of the principal surface of the supporting arm 15, a region that is the principal surface of the base portion 11 and is apart from the first bifurcated portion 17a by a distance S, and a corner portion (a portion indicated with W3 in FIG. 3B) of the first bifurcated portion 17a on the first vibration arm 13a side. Consequently, the tuning-fork type crystal resonator 30 of the comparative example has a structure where the first and second excitation electrodes 19a and 19b are extended without using the side surfaces of the supporting arm 15 and the inner bottom surfaces of the first and second bifurcated portions 17a and 17b.

In the tuning-fork type crystal resonator 30 of the comparative example, the width W1 of the portion provided on the principal surface of the supporting arm 15 in the first excitation electrode 19a was set to be 30 μm. A width W4 of the circumferential portion of the first bifurcated portion 17a of the base portion 11 in the first excitation electrode 19a was set to be 20 μm. The above-described width W3 was set to be 20 μm.

On the opposite-side surface of the tuning-fork, also the second excitation electrode 19b is extended so as to reach the side surface of the second vibration arm 13b on the supporting arm 15 side via a part of the principal surface of the supporting arm 15, a region that is the principal surface of the base portion 11 and is apart from the second bifurcated portion 17b by the distance S, and the corner portion of the second bifurcated portion 17b on the second vibration arm 13b side.

[2-2. Electrostatic Withstand Voltage Test Result]

An electrostatic withstand voltage test (ESD test) was performed on the respective tuning-fork type crystal resonators of the working example and the comparative example, so as to confirm the effects of the disclosure. The specimens used for the test were prepared by implementing the tuning-fork type crystal resonator illustrated in FIG. 3A and FIG. 3B in a predetermined ceramic package and then vacuum-sealed. In each of the working example and the comparative example, the number of specimens used for the test was ten.

As the electrostatic withstand voltage test, an HBM (human body model) test of JESD22-A114 standardized by JEDEC was performed. This test applies voltages to external terminals of the vacuum-sealed tuning-fork type crystal resonators described above based on standardized conditions and sequentially increases the applied voltage, and then evaluates the withstand voltage by a frequency variation amount (Δf/f) and a crystal impedance (CI) variation amount (ΔCI) of the specimens at that time. The applied voltages were set as five conditions of 100 V, 200 V, 300 V, 400 V, and 500 V. The voltage was applied five times at each of the voltages. The frequency variation and the CI variation were measured every time, and the specimen that deviated from the standard was determined to be a failure. The upper limit of the applied voltage was set to 500 V due to their required specifications.

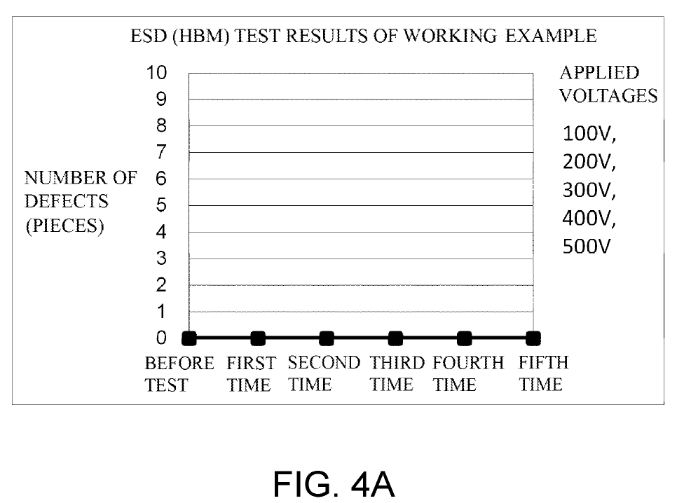

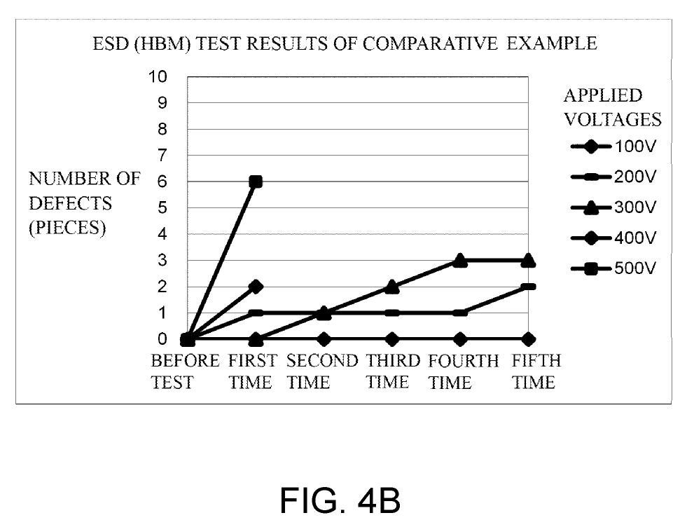

FIG. 4A is a diagram illustrating the electrostatic withstand voltage test results of the tuning-fork type crystal resonator of the working example, and FIG. 4B is a diagram illustrating the electrostatic withstand voltage test results of the tuning-fork type crystal resonator of the comparative example. As is apparent by comparing both diagrams, while a failure occurrence in the working example is zero, a failure in the comparative example occurs from the level of 200 V of the applied voltage. Thus, it is seen that the working example is much more excellent than the comparative example.

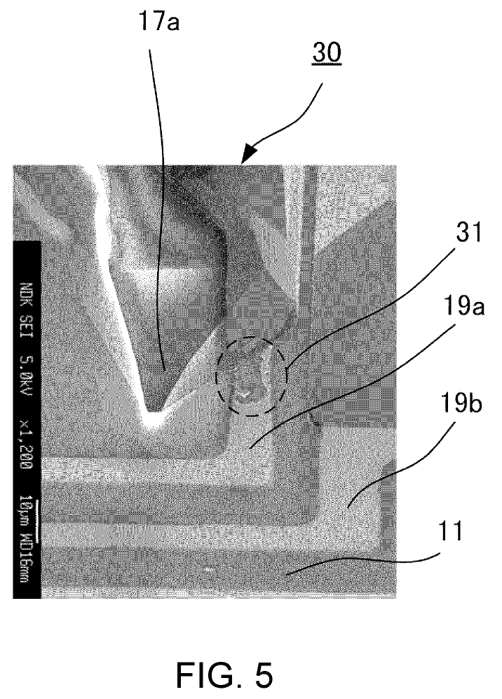

FIG. 5 is a photograph where the specimen of the comparative example that became defective at the electrostatic withstand voltage test was unsealed, and the failure cause was identified by SEM (scanning electron microscope). The shape of the bifurcated portion of the specimen (actual product) becomes an approximately V-shape and a complicated shape because of etching anisotropy of a crystallographic axis in a crystal. In FIG. 1A and FIG. 1B, and similar drawing, the bifurcated portion is indicated in a simplified shape; however, it is to be noted that the shape of the actual product observed with SEM is different from the shape indicated in FIG. 1A and FIG. 1B, and similar drawing.

A portion 31 surrounded with a dashed circle in FIG. 5 is a portion broken down by static electricity in the first excitation electrode 19a. The excitation electrode in this case is constituted of a two-layer thin film of chromium and gold, and it is seen that these metals are molten and scattered by static electricity. Since the breakdown portions are identical to the portion in FIG. 5 in any specimens that became defective, it is seen that a region where the excitation electrode is extended inside the first bifurcated portion 17a from the crystal-unit principal surface is a weak region of the electrostatic withstand voltage when viewing the first excitation electrode 19a side from the adhesion pad. From the results of the working example, it is seen that the lead-out structure of the excitation electrode of the disclosure ensures compensating for the weak region.

According to an examination of the inventor of this application, in the case of the tuning-fork type crystal resonator with a three-arm structure, when the excitation electrode side is viewed from the adhesion pad, the region where the excitation electrode is extended inside the bifurcated portion from the crystal-resonator principal surface was found to be the region (weak region) easily broken down by static electricity (see FIG. 5). The tuning-fork type crystal resonator of this disclosure obtains a structure with the excitation electrode widely extended in the weak region and thus ensures the tuning-fork type crystal resonator with an excellent electrostatic withstand voltage property.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A tuning-fork type crystal resonator, comprising:
a base portion;
a first vibration arm and a second vibration arm, parallelly extending from the base portion;
a supporting arm, extending from the base portion between the first vibration arm and the second vibration arm;
a first connection pad and a second connection pad, disposed on a part of the supporting arm to connect to outside; and
a first excitation electrode and a second excitation electrode, respectively extended from the first connection pad and the second connection pad to the first vibration arm and the second vibration arm, wherein
the first excitation electrode is extended from the first connection pad so as to reach a side surface of the first vibration arm on a supporting arm side, via a region including a part of a principal surface of the supporting arm and a part of a side surface of the supporting arm on a first vibration arm side, an inner bottom surface of a first bifurcated portion present between the supporting arm and the first vibration arm, and a circumferential portion of the first bifurcated portion in the base portion, and
the second excitation electrode is extended from the second connection pad so as to reach a side surface of the second vibration arm on a supporting arm side, via a region including a part of the principal surface of the supporting arm and a part of a side surface of the supporting arm on a second vibration arm side, an inner bottom surface of a second bifurcated portion present between the supporting arm and the second vibration arm, and a circumferential portion of the second bifurcated portion in the base portion.

2. The tuning-fork type crystal resonator according to claim 1, wherein
the first excitation electrode is substantially extended to a whole surface of the inner bottom surface of the first bifurcated portion, and
the second excitation electrode is substantially extended to a whole surface of the inner bottom surface of the second bifurcated portion.

3. The tuning-fork type crystal resonator according to claim 1, wherein
the first excitation electrode is further extended to a first side surface of the first vibration arm and a second side surface opposed to the first side surface of the first vibration arm, and a first principal surface of the second vibration arm and a second principal surface opposed to the first principal surface of the second vibration arm, and
the second excitation electrode is further extended to a first side surface of the second vibration arm and a second side surface opposed to the first side surface of the second vibration arm, and a first principal surface of the first vibration arm and a second principal surface opposed to the first principal surface of the first vibration arm.

4. The tuning-fork type crystal resonator according to claim 1, wherein
the first connection pad and the second connection pad are disposed on a first principal surface of the supporting arm, and
the second connection pad is connected to the second excitation electrode on a second principal surface of the supporting arm that is an opposite surface of the first principal surface of the supporting arm via the side surface of the supporting arm.
